(19) United States
(12) Patent Application Publication
(10) Pub. No.: US 2025/0234645 A1
(43) Pub. Date: Jul. 17, 2025

(54) SEMICONDUCTOR DEVICE

(71) Applicant: SAMSUNG ELECTRONICS CO., LTD., Suwon-si (KR)

(72) Inventors: Kyungmoo Kong, Suwon-si (KR); In-Mo Kim, Suwon-si (KR); Hoyong Park, Suwon-si (KR); Changyeon Yu, Suwon-si (KR); Hoon Jung, Suwon-si (KR)

(21) Appl. No.: 18/917,277

(22) Filed: Oct. 16, 2024

(30) Foreign Application Priority Data
Jan. 12, 2024 (KR) 10-2024-0005457

(51) Int. Cl. H01L 27/118

(52) U.S. Cl. CPC H10D 84/907; H10D 84/981

(57) ABSTRACT

A semiconductor device includes a first power line extended in a first direction, a second power line extended in the first direction and spaced apart from the first power line in a second direction crossing the first direction, a filler cell electrically connected to the first and second power lines, and a first logic cell and a second logic cell spaced apart from each other in the first direction, with the filler cell interposed therebetween. The filler cell includes a first source/drain pattern and a second source/drain pattern, a first gate electrode between the first and second source/drain patterns, a third source/drain pattern and a fourth source/drain pattern, and a second gate electrode between the third and fourth source/drain patterns.

### CROSS-REFERENCE TO RELATED APPLICATION(S)

This application claims priority to Korean Patent Application No. 10-2024-0005457, filed in the Korean Intellectual Property Office on Jan. 12, 2024, the entire contents of which are hereby incorporated by reference.

### BACKGROUND

A semiconductor device includes an integrated circuit consisting of metal-oxide-semiconductor field-effect transistors (MOS-FETs). To meet an increasing demand for the semiconductor device with a small pattern size and a reduced design rule, the MOS-FETs are being scaled down. The scale-down of the MOS-FETs may lead to deterioration in operation characteristics of the semiconductor device. Accordingly, a variety of studies are being conducted to overcome technical limitations associated with the scale-down of the semiconductor device and to provide high performance semiconductor device.

### SUMMARY

In general, in some aspects, the present disclosure is directed toward a semiconductor device with improved electrical and reliability characteristics and a method of fabricating the same.

According to some implementations, the present disclosure is directed to a semiconductor device may include a first power line extended in a first direction, a second power line extended in the first direction and spaced apart from the first power line in a second direction crossing the first direction, a filler cell electrically connected to the first and second power lines, and a first logic cell and a second logic cell spaced apart from each other in the first direction, with the filler cell interposed therebetween. The filler cell may include a first source/drain pattern and a second source/drain pattern electrically connected to the first power line, a first gate electrode between the first and second source/drain patterns, a third source/drain pattern and a fourth source/drain pattern electrically connected to the second power line, a second gate electrode between the third and fourth source/drain patterns, a first line conductive pattern overlapped with the first source/drain pattern, a second line conductive pattern overlapped with the second source/drain pattern, and a third line conductive pattern overlapped with the third source/drain pattern and the first gate electrode. The first gate electrode, the third source/drain pattern, and the third line conductive pattern may be disposed between the first line conductive pattern and the second line conductive pattern.

According to some implementations, the present disclosure is directed to a semiconductor device may include a first power line extended in a first direction, a second power line extended in the first direction and spaced apart from the first power line in a second direction crossing the first direction, a filler cell electrically connected to the first and second power lines, and a first logic cell and a second logic cell spaced apart from each other in the first direction, with the filler cell interposed therebetween. The filler cell may include a first source/drain pattern and a second source/drain pattern electrically connected to the first power line, a first gate electrode between the first and second source/drain patterns, a third source/drain pattern and a fourth source/drain pattern electrically connected to the second power line, and a second gate electrode between the third and fourth source/drain patterns. A distance between the first source/drain pattern and the fourth source/drain pattern in the first direction may be larger than a distance between the third source/drain pattern and the fourth source/drain pattern in the first direction.

According to some implementations, the present disclosure is directed to a semiconductor device may include a first power line extended in a first direction, a second power line extended in the first direction and spaced apart from the first power line in a second direction crossing the first direction, a filler cell electrically connected to the first and second power lines, and a first logic cell and a second logic cell spaced apart from each other in the first direction, with the filler cell interposed therebetween. The filler cell may include a first source/drain pattern and a second source/drain pattern electrically connected to the first power line, a first gate electrode between the first and second source/drain patterns, a third source/drain pattern and a fourth source/drain pattern electrically connected to the second power line, a second gate electrode between the third and fourth source/drain patterns, a first line conductive pattern overlapped with the first source/drain pattern, a second line conductive pattern overlapped with the second source/drain pattern, a third line conductive pattern overlapped with the third source/drain pattern and the first gate electrode, a first active contact in contact with the first source/drain pattern and the first line conductive pattern, a second active contact in contact with the third source/drain pattern and the third line conductive pattern, a first line contact in contact with the first line conductive pattern and the first power line, a second line contact in contact with the second line conductive pattern and the first power line, a third line contact in contact with the third line conductive pattern and the second power line, and a gate contact in contact with the first gate electrode and the third line conductive pattern. Each of the first to third line conductive patterns may be overlapped with the first power line and the second power line.

### BRIEF DESCRIPTION OF THE DRAWINGS

Example implementations will be more clearly understood from the following detailed description, taken in conjunction with the accompanying drawings.

FIG. 1 is a plan view schematically illustrating an example of a semiconductor device according to some implementations.

FIG. 2A is a plan view illustrating an example of a filler cell of FIG. 1 according to some implementations.

FIG. 2B is a sectional view taken along a line A1-A1′ of FIG. 2A according to some implementations.

FIG. 2C is a sectional view taken along a line B1-B1′ of FIG. 2A according to some implementations.

FIG. 2D is a sectional view taken along a line C1-C1′ of FIG. 2A according to some implementations.

FIG. 3 is a plan view illustrating an example of a filler cell of a semiconductor device according to some implementations.

FIG. 4 is a plan view illustrating an example of a filler cell of a semiconductor device according to some implementations.

FIG. 5 is a plan view illustrating an example of a filler cell of a semiconductor device according to some implementations.

FIG. 6 is a plan view illustrating an example of a filler cell of a semiconductor device according to some implementations.

FIG. 7 is a plan view schematically illustrating an example of a semiconductor device according to some implementations.

FIG. 8A is a plan view illustrating an example of a semiconductor device according to some implementations.

FIG. 8B is a sectional view taken along a line A2-A2′ of FIG. 8A according to some implementations.

FIG. 8C is a sectional view taken along a line B2-B2′ of FIG. 8A according to some implementations.

### DETAILED DESCRIPTION

Hereinafter, example implementations will be explained in detail with reference to the accompanying drawings.

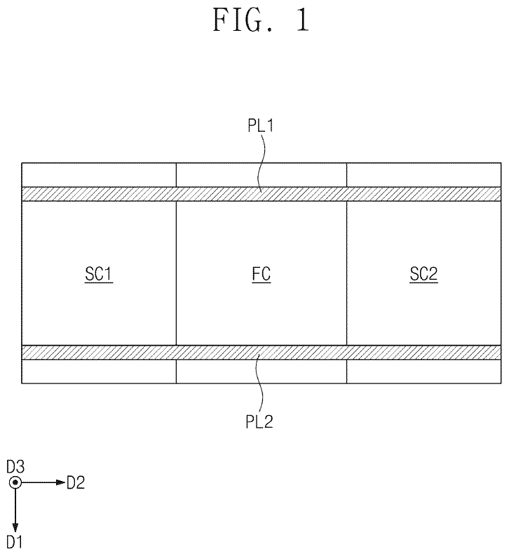

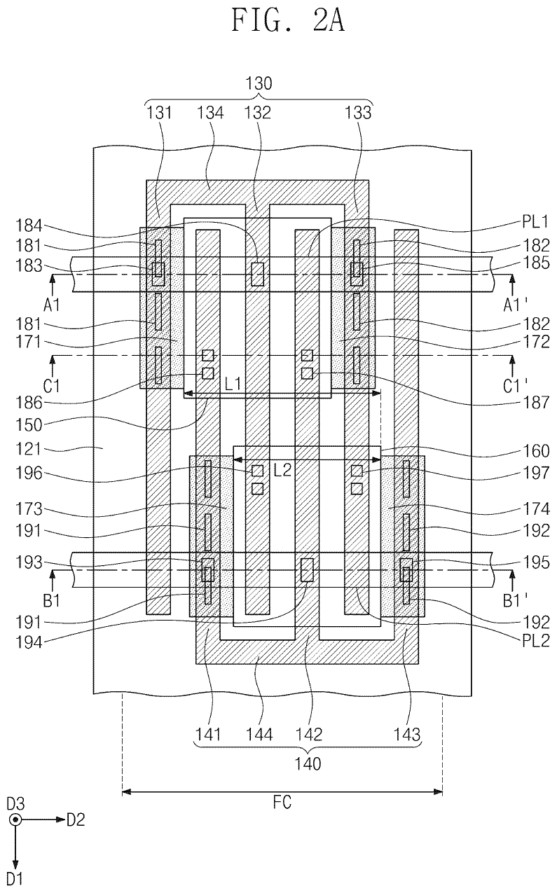

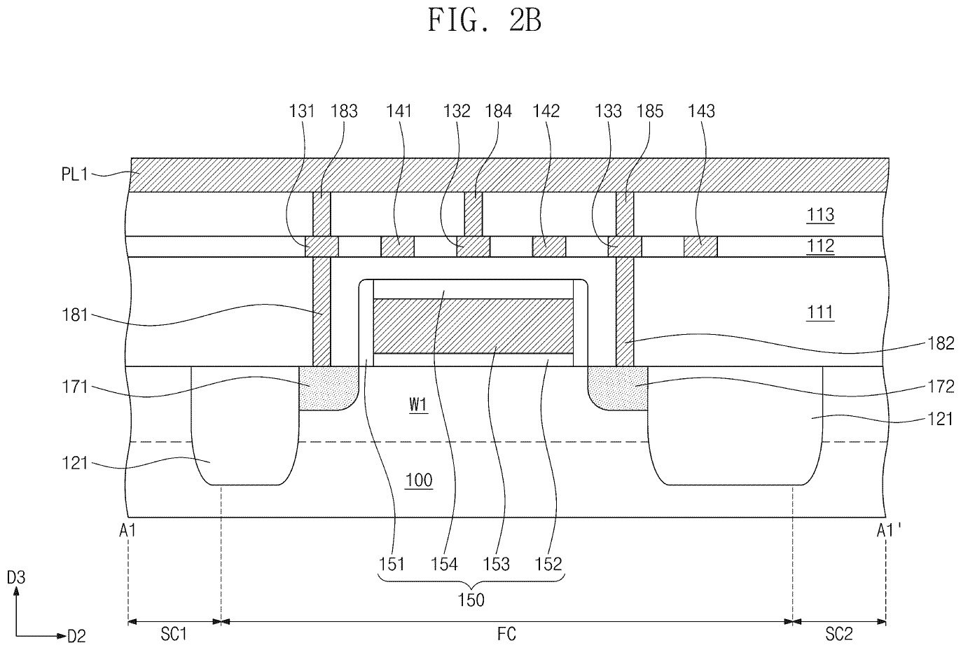

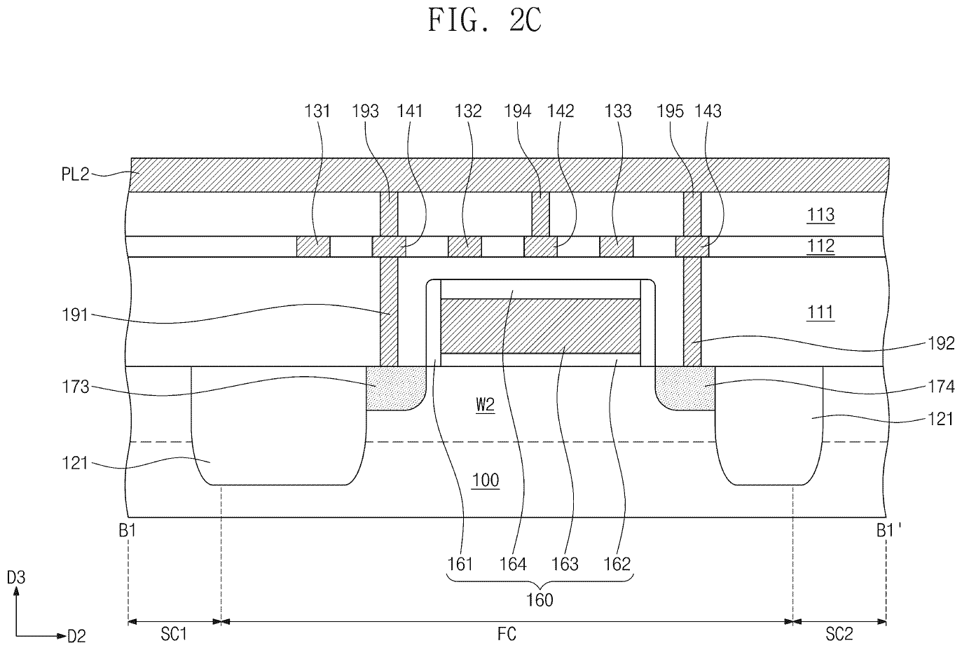

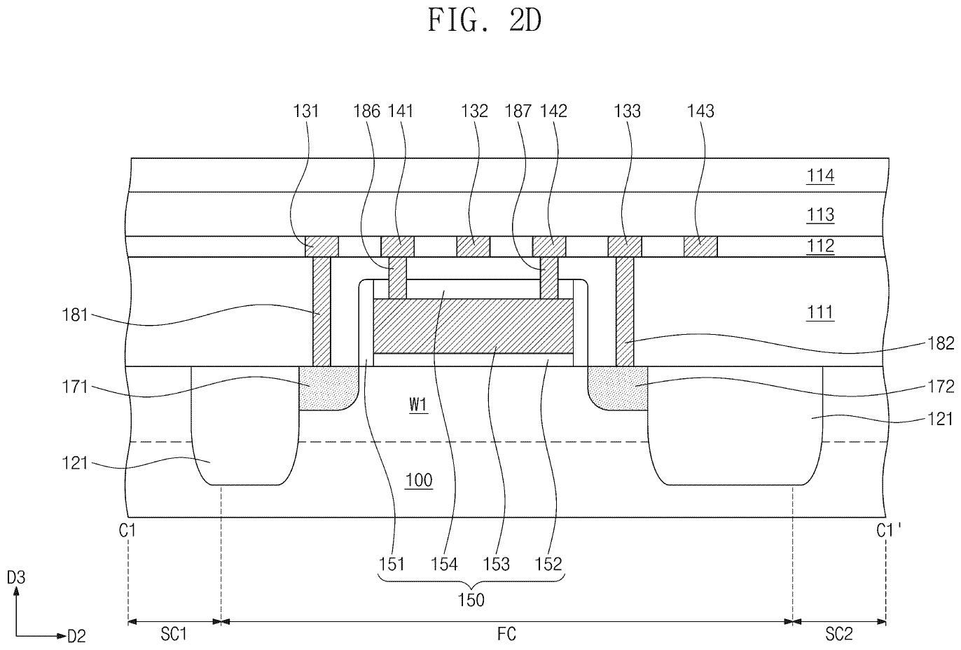

FIG. 1 is a plan view schematically illustrating an example of a semiconductor device according to some implementations. FIG. 2A is a plan view illustrating an example of a filler cell of FIG. 1 according to some implementations. FIG. 2B is a sectional view taken along a line A1-A1′ of FIG. 2A according to some implementations. FIG. 2C is a sectional view taken along a line B1-B1′ of FIG. 2A according to some implementations. FIG. 2D is a sectional view taken along a line C1-C1′ of FIG. 2A according to some implementations.

In FIG. 1, a semiconductor device may include a first logic cell SC1, a second logic cell SC2, and a filler cell FC. The first logic cell SC1, the second logic cell SC2, and the filler cell FC may be distinct from each other on a plan view, which is defined by a first direction D1 and a second direction D2. The first and second directions D1 and D2 may not be parallel to each other. As an example, the first and second directions D1 and D2 may be horizontal directions that are orthogonal to each other.

The first logic cell SC1 and the second logic cell SC2 may be spaced apart from each other in the second direction D2. The filler cell FC may be disposed between the first logic cell SC1 and the second logic cell SC2.

A first power line PL1 and a second power line PL2 may be provided. The first and second power lines PL1 and PL2 may be extended in the second direction D2. The first and second power lines PL1 and PL2 may be spaced apart from each other in the first direction D1. The first logic cell SC1, the second logic cell SC2, and the filler cell FC may be overlapped with the first and second power lines PL1 and PL2 in a third direction D3. The third direction D3 may not be parallel to the first and second directions D1 and D2. In some implementations, the third direction D3 may be a vertical direction that is orthogonal to the first and second directions D1 and D2.

In some implementations, the first power line PL1 may be a conduction path, to which a drain voltage VDD is provided, the second power line PL2 may be a conduction path, to which a source voltage (VSS) is provided. As an example, the first power line PL1 may be a conduction path, to which a power voltage is provided, and the second power line PL2 may be a conduction path, to which a ground voltage is provided. In some implementations, the first logic cell SC1, the second logic cell SC2, and the filler cell FC may be electrically connected to the first and second power lines PL1 and PL2.

The first logic cell SC1 and the second logic cell SC2 may mean a logic device (e.g., AND, OR, XOR, XNOR, inverter, and so forth), which is configured to execute a specific function. The first logic cell SC1 and the second logic cell SC2 may include transistors constituting the logic device and interconnection lines connecting transistors to each other.

The filler cell FC may include a p-type MOSFET and an n-ty MOSFET, which are operated as a decoupling capacitor.

In FIGS. 2A, 2B, 2C, and 2D, the semiconductor device may include a substrate 100. The first logic cell SC1, the second logic cell SC2, and the filler cell FC may be disposed on the substrate 100. The substrate 100 may be a semiconductor substrate, an insulating substrate, a silicon-on-insulator (SOI) substrate, or a germanium-on-insulator (GOI) substrate. In some implementations, the semiconductor substrate may be formed of or include silicon, germanium, silicon-germanium, GaP, or GaAs.

The filler cell FC may include a first well region W1 and a second well region W2. Each of the first and second well regions W1 and W2 may be a portion of the substrate 100. A device isolation layer 121 may be provided on the substrate 100. Each of the first and second well regions W1 and W2 may be enclosed by the device isolation layer 121. The first and second well regions W1 and W2 may be spaced apart from the first direction D1 by the device isolation layer 121. The device isolation layer 121 may include an insulating material.

The first well region W1 may include impurities of a first conductivity type, and the second well region W2 may include impurities, which are of a second conductivity type different from the first conductivity type. In some implementations, the first well region W1 may include n-type impurities, and the second well region W2 may include p-type impurities.

The filler cell FC may further include a first source/drain pattern 171 and a second source/drain pattern 172 on the first well region W1 and a third source/drain pattern 173 and a fourth source/drain pattern 174 on the second well region W2. Each of the first to fourth source/drain patterns 171, 172, 173, and 174 may be a portion of the substrate 100.

The first and second source/drain patterns 171 and 172 may include impurities of the second conductivity type. The third and fourth source/drain patterns 173 and 174 may include impurities of the first conductivity type.

The first and second source/drain patterns 171 and 172 may be overlapped with the first power line PL1 in the third direction D3. The first and second source/drain patterns 171 and 172 may be electrically connected to the first power line PL1. The third and fourth source/drain patterns 173 and 174 may be overlapped with the second power line PL2 in the third direction D3. The third and fourth source/drain patterns 173 and 174 may be electrically connected to the second power line PL2.

A distance L1 between the first and fourth source/drain patterns 171 and 174 in the second direction D2 may be larger than a distance L2 between the third and fourth source/drain patterns 173 and 174 in the second direction D2. A distance between the first source/drain pattern 171 and the first logic cell SC1 in the second direction D2 may be smaller than a distance between the third source/drain pattern 173 and the first logic cell SC1 in the second direction D2. A distance between the second source/drain pattern 172 and the second logic cell SC2 in the second direction D2 may be larger than a distance between the fourth source/drain pattern 174 and the second logic cell SC2 in the second direction D2.

The filler cell FC may further include a first gate structure 150 on the first well region W1 and a second gate structure 160 on the second well region W2. The first gate structure 150 may be disposed between the first and second source/drain patterns 171 and 172. The second gate structure 160 may be disposed between the third and fourth source/drain patterns 173 and 174. The first gate structure 150 may include a first gate insulating layer 152, a first gate electrode 153, a first gate capping layer 154, and first gate spacers 151. The first gate insulating layer 152, the first gate capping layer 154, and the first gate spacers 151 may include an insulating material. The first gate electrode 153 may include a conductive material.

The first gate electrode 153 may be provided on the first gate insulating layer 152. The first gate capping layer 154 may be provided on the first gate electrode 153. The first gate spacers 151 may be provided on opposite side surfaces of the first gate insulating layer 152, the first gate electrode 153, and the first gate capping layer 154. The first gate electrode 153 may be disposed between the first and second source/drain patterns 171 and 172. The first gate electrode 153 may be overlapped with the first power line PL1 in the third direction D3.

The second gate structure 160 may include a second gate insulating layer 162, a second gate electrode 163, a second gate capping layer 164, and second gate spacers 161. The second gate insulating layer 162, the second gate capping layer 164, and the second gate spacers 161 may include an insulating material. The second gate electrode 163 may include a conductive material. The second gate electrode 163 may be disposed between the third and fourth source/drain patterns 173 and 174. The second gate electrode 163 may be overlapped with the second power line PL2 in the third direction D3.

A distance between the first gate electrode 153 and the first logic cell SC1 in the second direction D2 may be smaller than a distance between the second gate electrode 163 and the first logic cell SC1 in the second direction D2. A distance between the first gate electrode 153 and the second logic cell SC2 in the second direction D2 may be larger than a distance between the second gate electrode 163 and the second logic cell SC2 in the second direction D2.

The third source/drain pattern 173 and the first gate electrode 153 may be overlapped with a single straight line, which is extended in the first direction D1, in the third direction D3. The second source/drain pattern 172 and the second gate electrode 163 may be overlapped with a single straight line, which is extended in the first direction D1, in the third direction D3.

A first insulating layer 111 may be provided on the first well region W1, the second well region W2, and the device isolation layer 121. A second insulating layer 112 may be provided on the first insulating layer 111. A third insulating layer 113 may be provided on the second insulating layer 112. A fourth insulating layer 114 may be provided on the third insulating layer 113. The first to fourth insulating layers 111, 112, 113, and 114 may include an insulating material.

The filler cell FC may further include first active contacts 181, second active contacts 182, third active contacts 191, and fourth active contacts 192. Each of the first to fourth active contacts 181, 182, 191, and 192 may be extended in the third direction D3 to penetrate the first insulating layer 111. The first to fourth active contacts 181, 182, 191, and 192 may include a conductive material.

Bottom surfaces of the first active contacts 181 may be in contact with atop surface of the first source/drain pattern 171. Bottom surfaces of the second active contacts 182 may be in contact with a top surface of the second source/drain pattern 172. Bottom surfaces of the third active contacts 191 may be in contact with a top surface of the third source/drain pattern 173. Bottom surfaces of the fourth active contacts 192 may be in contact with a top surface of the fourth source/drain pattern 174.

The filler cell FC may further include first gate contacts 186, second gate contacts 187, third gate contacts 196, and fourth gate contacts 197. Each of the first and second gate contacts 186 and 187 may be extended in the third direction D3 to penetrate the first insulating layer 111 and the first gate capping layer 154. Each of the third and fourth gate contacts 196 and 197 may be extended in the third direction D3 to penetrate the first insulating layer 111 and the second gate capping layer 164. The first to fourth gate contacts 186, 187, 196, and 197 may include a conductive material.

Bottom surfaces of the first and second gate contacts 186 and 187 may be in contact with a top surface of the first gate electrode 153. Bottom surfaces of the third and fourth gate contacts 196 and 197 may be in contact with a top surface of the second gate electrode 163. The first gate contacts 186, the third active contacts 191, and the third source/drain pattern 173 may be overlapped with a single straight line, which is extended in the first direction D1, in the third direction D3. The fourth gate contacts 197, the second active contacts 182, and the second source/drain pattern 172 may be overlapped with a single straight line, which is extended in the first direction D1, in the third direction D3.

The filler cell FC may further include a first conductive structure 130 and a second conductive structure 140. The first conductive structure 130 and the second conductive structure 140 may be disposed in the second insulating layer 112. The first conductive structure 130 and the second conductive structure 140 may include a conductive material.

The first conductive structure 130 may include a first line conductive pattern 131, a second line conductive pattern 132, a third line conductive pattern 133, and a first connection conductive pattern 134. The first to third line conductive patterns 131, 132, and 133 may be extended in the first direction D1. Each of the first to third line conductive patterns 131, 132, and 133 may be longer in the first direction D1 than in the second direction D2. The first connection conductive pattern 134 may be extended in the second direction D2. The first connection conductive pattern 134 may be longer in the second direction D2 than in the first direction D1. The first connection conductive pattern 134 may be provided to connect the first to third line conductive patterns 131, 132, and 133 to each other. In an embodiment, the first connection conductive pattern 134 and the first to third line conductive patterns 131, 132, and 133 may be connected to each other, without an interface, to form a single object.

The second conductive structure 140 may include a fourth line conductive pattern 141, a fifth line conductive pattern 142, a sixth line conductive pattern 143, and a second connection conductive pattern 144. The fourth to sixth line conductive patterns 141, 142, and 143 may be extended in the first direction D1. The second connection conductive pattern 144 may be extended in the second direction D2. The second connection conductive pattern 144 may be provided to connect the fourth to sixth line conductive patterns 141, 142, and 143 to each other.

The first line conductive pattern 131 may be overlapped with the first source/drain pattern 171 in the third direction D3. A bottom surface of the first line conductive pattern 131 may be in contact with top surfaces of the first active contacts 181. The second line conductive pattern 132 may be overlapped with the first gate electrode 153 and the second gate electrode 163 in the third direction D3. A bottom surface of the second line conductive pattern 132 may be in contact with top surfaces of the third gate contacts 196. The third line conductive pattern 133 may be overlapped with the second source/drain pattern 172 and the second gate electrode 163 in the third direction D3. A bottom surface of the third line conductive pattern 133 may be in contact with top surfaces of the second active contacts 182 and top surfaces of the fourth gate contacts 197.

The fourth line conductive pattern 141 may be overlapped with the third source/drain pattern 173 and the first gate electrode 153 in the third direction D3. A bottom surface of the fourth line conductive pattern 141 may be in contact with top surfaces of the third active contacts 191 and top surfaces of the first gate contacts 186. The fifth line conductive pattern 142 may be overlapped with the first gate electrode 153 and the second gate electrode 163 in the third direction D3. A bottom surface of the fifth line conductive pattern 142 may be in contact with top surfaces of the second gate contacts 187. The sixth line conductive pattern 143 may be overlapped with the fourth source/drain pattern 174 in the third direction D3. A bottom surface of the sixth line conductive pattern 143 may be in contact with top surfaces of the fourth active contacts 192.

The first and second gate electrodes 153 and 163, the second and third source/drain patterns 172 and 173, and the second to fifth line conductive patterns 132, 133, 141, and 142 may be disposed between the first and sixth line conductive patterns 131 and 143. The first gate electrode 153, the third source/drain pattern 173, and the second, fourth, and fifth line conductive patterns 132, 141, and 142 may be disposed between the first and third line conductive patterns 131 and 133. Each of the first to sixth line conductive patterns 131, 132, 133, 141, 142, and 143 may be overlapped with the first and second power lines PL1 and PL2 in the third direction D3.

The first and second gate electrodes 153 and 163, the first to fourth source/drain patterns 171, 172, 173, and 174, and the first and second power lines PL1 and PL2 may be disposed between the first connection conductive pattern 134 and the second connection conductive pattern 144.

The first connection conductive pattern 134 may not be overlapped with the first gate electrode 153 in the third direction D3. A distance between the first connection conductive pattern 134 and the second power line PL2 in the first direction D1 may be larger than a distance between the first and second power lines PL1 and PL2 in the first direction D1. The second connection conductive pattern 144 may not be overlapped with the second gate electrode 163 in the third direction D3.

The filler cell FC may further include a first line contact 183, a second line contact 184, a third line contact 185, a fourth line contact 193, a fifth line contact 194, and a sixth line contact 195. Each of the first to sixth line contacts 183, 184, 185, 193, 194, and 195 may be extended in the third direction D3 to penetrate the third insulating layer 113. The first to sixth line contacts 183, 184, 185, 193, 194, and 195 may include a conductive material.

The first line contact 183 may be overlapped with one of the first active contacts 181 in the third direction D3. A bottom surface of the first line contact 183 may be in contact with a top surface of the first line conductive pattern 131. A bottom surface of the second line contact 184 may be in contact with a top surface of the second line conductive pattern 132. The second line contact 184 and the third gate contacts 196 may be overlapped with a single straight line, which is extended in the first direction D1, in the third direction D3. The third line contact 185 may be overlapped with one of the second active contacts 182 in the third direction D3. A bottom surface of the third line contact 185 may be in contact with a top surface of the third line conductive pattern 133. The third line contact 185 and the fourth gate contacts 197 may be overlapped with a single straight line, which is extended in the first direction D1, in the third direction D3.

The fourth line contact 193 may be overlapped with one of the third active contacts 191 in the third direction D3. A bottom surface of the fourth line contact 193 may be in contact with a top surface of the fourth line conductive pattern 141. The fourth line contact 193 and the first gate contacts 186 may be overlapped with a single straight line, which is extended in the first direction D1, in the third direction D3. A bottom surface of the fifth line contact 194 may be in contact with a top surface of the fifth line conductive pattern 142. The fifth line contact 194 and the second gate contacts 187 may be overlapped with a single straight line, which is extended in the first direction D1, in the third direction D3. The sixth line contact 195 may be overlapped with one of the fourth active contacts 192 in the third direction D3. A bottom surface of the sixth line contact 195 may be in contact with a top surface of the sixth line conductive pattern 143.

The first and second power lines PL1 and PL2 may be provided in the fourth insulating layer 114. A bottom surface of the first power line PL1 may be in contact with top surfaces of the first to third line contacts 183, 184, and 185. A bottom surface of the second power line PL2 may be in contact with top surfaces of the fourth to sixth line contacts 193, 194, and 195.

In the semiconductor device according to the present disclosure, since the gate structures are asymmetrically disposed in the filler cell, it may be possible to maximize the number of the line conductive patterns disposed in the filler cell.

In the semiconductor device according to the present disclosure, since the filler cell includes the line conductive patterns, it may be possible to further increase a capacitance between the line conductive patterns and a capacitance between the line conductive pattern and the gate electrode. Accordingly, the filler cell may have an increased capacitance per unit area.

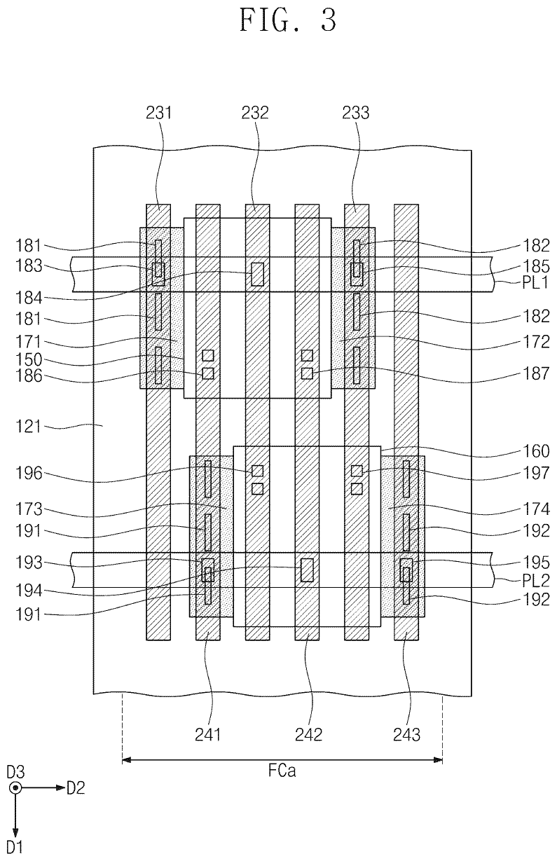

FIG. 3 is a plan view illustrating an example of a filler cell of a semiconductor device according to some implementations. Except for technical features to be described below, the semiconductor device of FIG. 3 may be provided to have technical features that are similar to the semiconductor device of FIGS. 1, 2A, 2B, 2C, and 2D.

In FIG. 3, a filler cell FCa may include a first line conductive pattern 231, a second line conductive pattern 232, a third line conductive pattern 233, a fourth line conductive pattern 241, a fifth line conductive pattern 242, and a sixth line conductive pattern 243. In some implementations, the first to sixth line conductive patterns 231, 232, 233, 241, 242, and 243 may have the same length in the first direction D1. The first to third line conductive patterns 231, 232, and 233 may be electrically connected to each other through the first power line PL1. The fourth to sixth line conductive patterns 241, 242, and 243 may be electrically connected to each other through the second power line PL2.

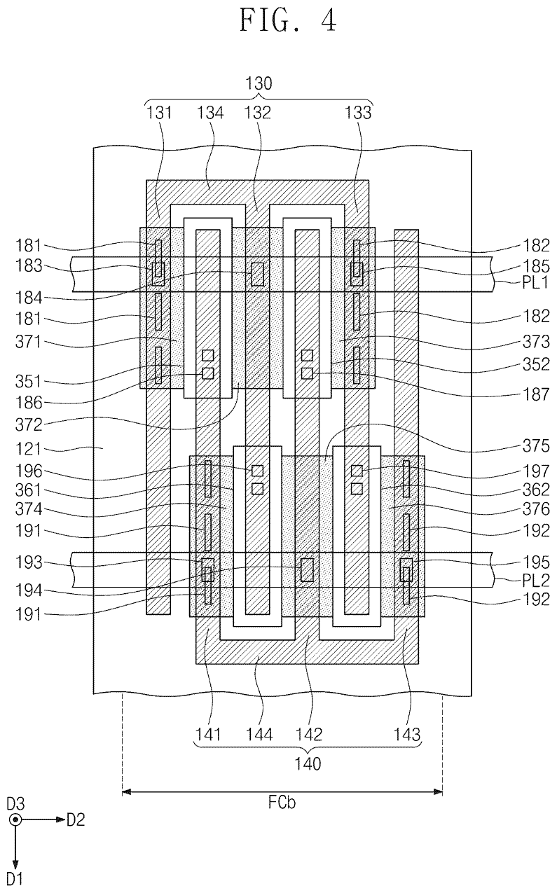

FIG. 4 is a plan view illustrating an example of a filler cell of a semiconductor device according to some implementations. Except for technical features to be described below, the semiconductor device of FIG. 4 may be provided to have technical features that are similar to the semiconductor device of FIGS. 1, 2A, 2B, 2C, and 2D.

In FIG. 4, a filler cell FCb may include a first source/drain pattern 371, a second source/drain pattern 372, a third source/drain pattern 373, a fourth source/drain pattern 374, a fifth source/drain pattern 375, and a sixth source/drain pattern 376.

The filler cell FCb may include a first gate structure 351 between the first and second source/drain patterns 371 and 372, a second gate structure 352 between the second and third source/drain patterns 372 and 373, a third gate structure 361 between the fourth and fifth source/drain patterns 374 and 375, and a fourth gate structure 362 between the fifth and sixth source/drain patterns 375 and 376.

The second line conductive pattern 132 may be overlapped with the second source/drain pattern 372 and third gate structure 361 in the third direction D3. The fifth line conductive pattern 142 may be overlapped with the fifth source/drain pattern 375 and the second gate structure 352 in the third direction D3.

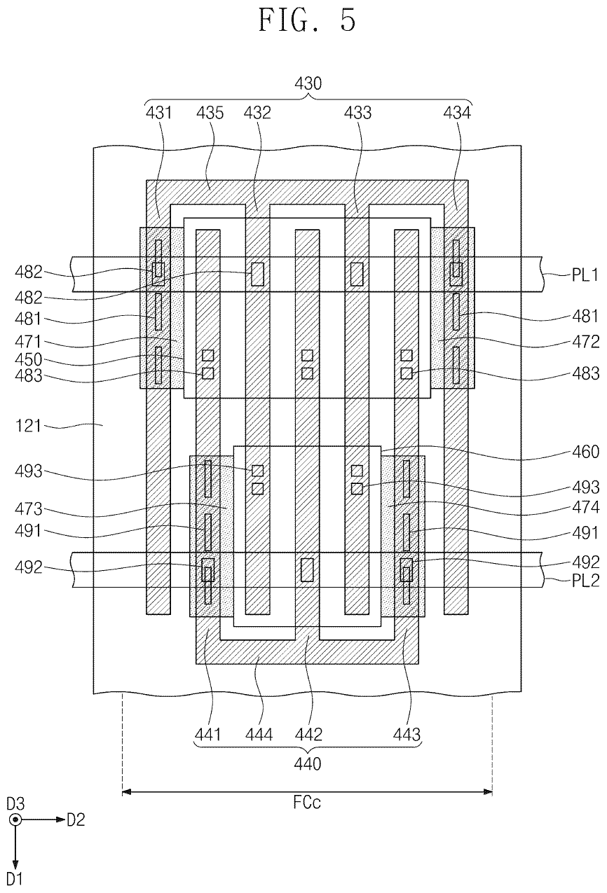

FIG. 5 is a plan view illustrating an example of a filler cell of a semiconductor device according to some implementations. Except for technical features to be described below, the semiconductor device of FIG. 5 may be provided to have technical features that are similar to the semiconductor device of FIGS. 1, 2A, 2B, 2C, and 2D.

In FIG. 5, a filler cell FCc may include a first gate structure 450, which is overlapped with the first power line PL1 in the third direction D3, and a second gate structure 460, which is overlapped with the second power line PL2 in the third direction D3. A length of the first gate structure 450 in the second direction D2 may be larger than a length of the second gate structure 460 in the second direction D2. The first gate structure 450 may include a first gate electrode, and the second gate structure 460 may include a second gate electrode. A length of the first gate electrode in the second direction D2 may be larger than a length of the second gate electrode in the second direction D2.

The filler cell FCc may include a first conductive structure 430, which is electrically connected to the first power line PL1, and a second conductive structure 440, which is electrically connected to the second power line PL2.

The first conductive structure 430 may include a first line conductive pattern 431, a second line conductive pattern 432, a third line conductive pattern 433, a fourth line conductive pattern 434, and a first connection conductive pattern 435. The second conductive structure 440 may include a fifth line conductive pattern 441, a sixth line conductive pattern 442, a seventh line conductive pattern 443, and a second connection conductive pattern 444.

The second, third, fifth, sixth, and seventh line conductive patterns 432, 433, 441, 442, and 443 and the first and second gate structures 450 and 460 may be disposed between the first and fourth line conductive patterns 431 and 434.

A distance between a first source/drain pattern 471 and a second source/drain pattern 472 in the second direction D2 may be larger than a distance between a third source/drain pattern 473 and a fourth source/drain pattern 474 in the second direction D2.

The filler cell FCc may include first active contacts 481 electrically connecting the first and second source/drain patterns 471 and 472 to the first conductive structure 430, first gate contacts 483 electrically connecting the first gate structure 450 to the first conductive structure 430, and first line contacts 482 electrically connecting the first conductive structure 430 to the first power line PL1.

The filler cell FCc may include second active contacts 491 electrically connecting the third and fourth source/drain patterns 473 and 474 to the second conductive structure 440, second gate contacts 493 electrically connecting the second gate structure 460 to the second conductive structure 440, and second line contacts 492 electrically connecting the second conductive structure 440 to the second power line PL2.

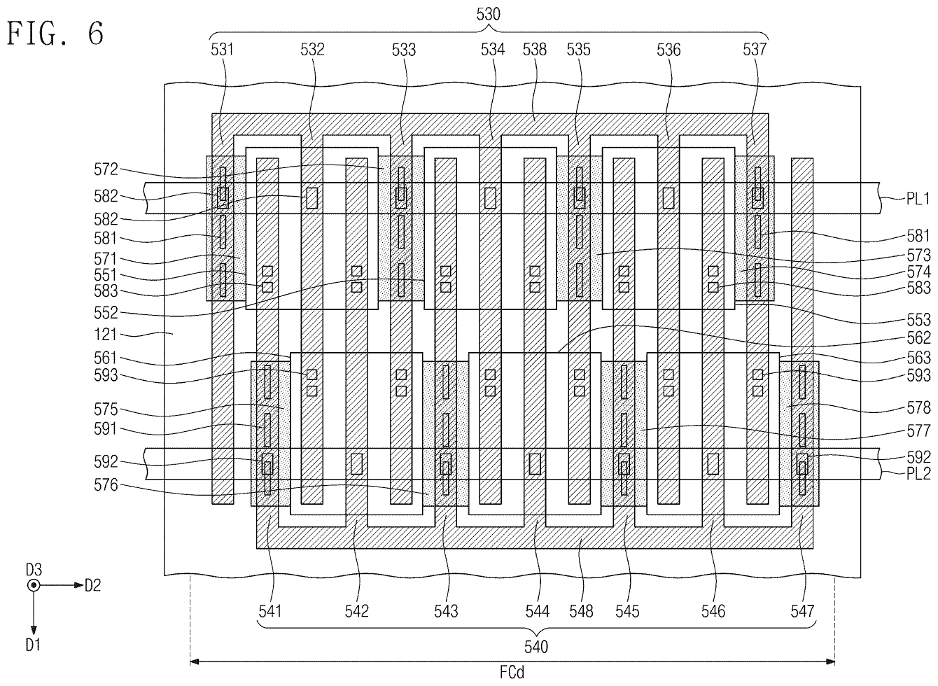

FIG. 6 is a plan view illustrating an example of a filler cell of a semiconductor device according to some implementations. Except for technical features to be described below, the semiconductor device of FIG. 6 may be provided to have technical features that are similar to the semiconductor device of FIGS. 1, 2A, 2B, 2C, and 2D.

In FIG. 6, a filler cell FCd may include a first gate structure 551, a second gate structure 552, and a third gate structure 553, which are overlapped with the first power line PL1 in the third direction D3, and a fourth gate structure 561, a fifth gate structure 562, and a sixth gate structure 563, which are overlapped with the second power line PL2 in the third direction D3.

The filler cell FCd may include the first to fourth source/drain patterns 571, 572, 573, and 574, which are alternately arranged with the first to third gate structures 551, 552, and 553 in the second direction D2. The filler cell FCd may include the fifth to eighth source/drain patterns 575, 576, 577, and 578, which are alternately arranged with the fourth to sixth gate structures 561, 562, and 563 in the second direction D2.

The filler cell FCd may include a first conductive structure 530, which is electrically connected to the first to fourth source/drain patterns 571, 572, 573, and 574, and a second conductive structure 540, which is electrically connected to the fifth to eighth source/drain patterns 575, 576, 577, and 578. The first conductive structure 530 may include a first line conductive pattern 531, a second line conductive pattern 532, a third line conductive pattern 533, a fourth line conductive pattern 534, a fifth line conductive pattern 535, a sixth line conductive pattern 536, a seventh line conductive pattern 537, and a first connection conductive pattern 538. The second conductive structure 540 may include an eighth line conductive pattern 541, a ninth line conductive pattern 542, a tenth line conductive pattern 543, an eleventh line conductive pattern 544, a twelfth line conductive pattern 545, a thirteenth line conductive pattern 546, a fourteenth line conductive pattern 547, and a second connection conductive pattern 548.

The filler cell FCd may include first active contacts 581 electrically connecting the first to fourth source/drain patterns 571, 572, 573, and 574 to the first conductive structure 530, first gate contacts 583 electrically connecting the first to third gate structures 551, 552, and 553 to the first conductive structure 530, and first line contacts 582 electrically connecting the first conductive structure 530 to the first power line PL1.

The filler cell FCd may include second active contacts 591 electrically connecting the fifth to eighth source/drain patterns 575, 576, 577, and 578 to the second conductive structure 540, second gate contacts 593 electrically connecting the fourth to sixth gate structures 561, 562, and 563 to the second conductive structure 540, and second line contacts 592 electrically connecting the second conductive structure 540 to the second power line PL2.

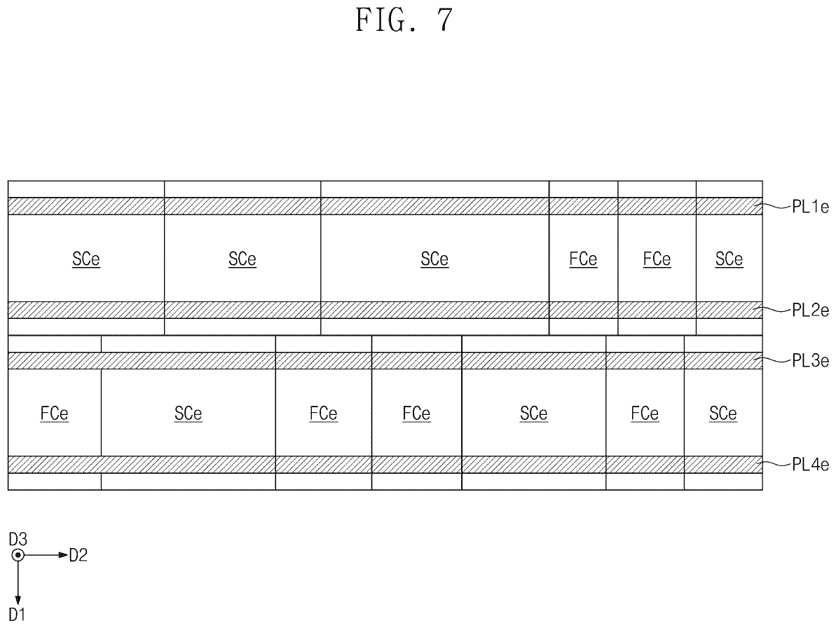

FIG. 7 is a plan view schematically illustrating an example of a semiconductor device according to some implementations. In FIG. 7, the semiconductor device may include a first power line PL1e, a second power line PL2e, a third power line PL3e, and a fourth power line PL4e, which are extended in the second direction D2. The semiconductor device may include logic cells SCe and filler cells FCe. The logic cells SCe may include the logic cells SCe, which are overlapped with the first and second power lines PL1e and PL2e in the third direction D3, and the logic cells SCe, which are overlapped with the third and fourth power lines PL3e and PL4e in the third direction D3. The filler cells FCe may include the filler cells FCe, which are overlapped with the first and second power lines PL1e and PL2e in the third direction D3, and the filler cells FCe, which are overlapped with the third and fourth power lines PL3e and PL4e in the third direction D3. The filler cell FCe may be provided to have substantially the same or similar features as the filler cell FC described in FIG. 2A to 2D.

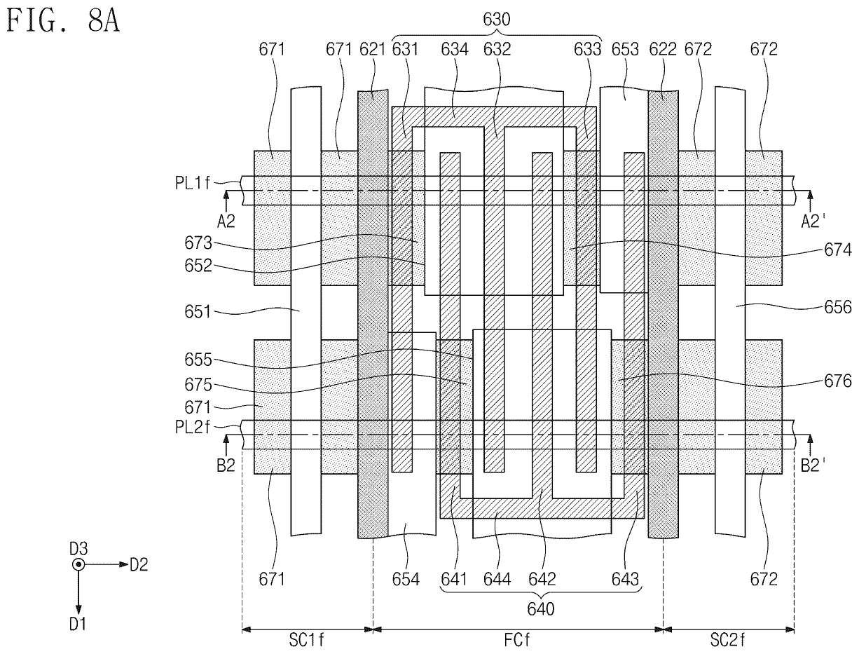

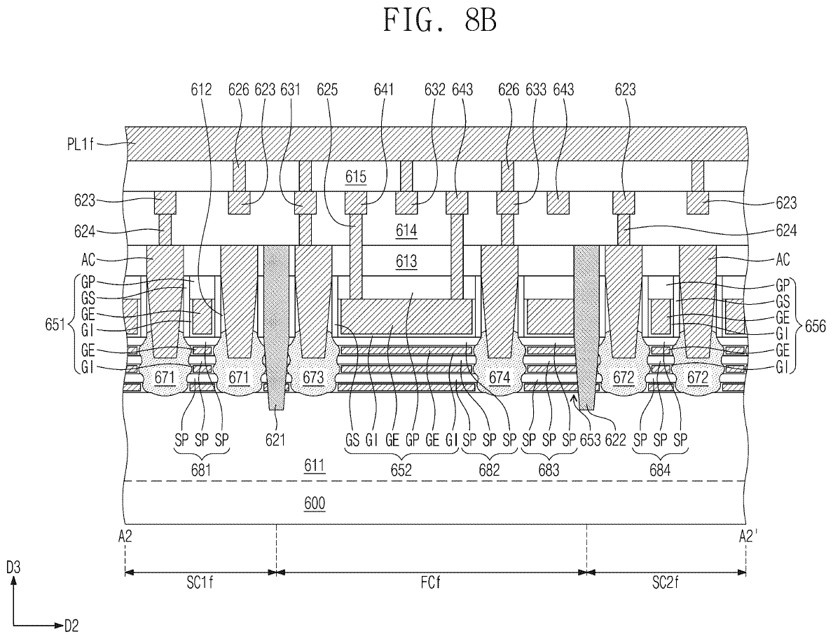

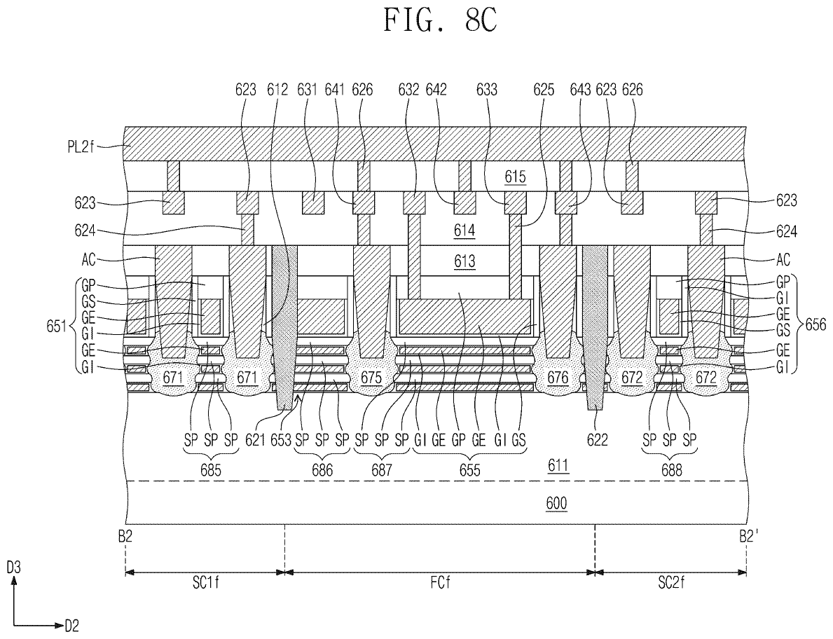

FIG. 8A is a plan view illustrating an example of a semiconductor device according to some implementations. FIG. 8B is a sectional view taken along line A2-A2′ of FIG. 8A according to some implementations. FIG. 8C is a sectional view taken along a line B2-B2′ of FIG. 8A according to some implementations.

In FIGS. 8A, 8B, and 8C, the semiconductor device may include the first logic cell SC1f, the second logic cell SC2f, and the filler cell FCf between the first logic cell SC1f and the second logic cell SC2f.

The semiconductor device may include a substrate 600. The substrate 600 may include active patterns 611. The active patterns 611 may be defined by a trench on the substrate 600. The active pattern 611 may be a portion of the substrate 600 protruding in the third direction D3.

A first logic channel pattern 681, a second logic channel pattern 684, a first filler channel pattern 682, and a second filler channel pattern 683 may be provided to be overlapped with the first power line PL1f in the third direction D3. A third logic channel pattern 685, a fourth logic channel pattern 688, a third filler channel pattern 686, and a fourth filler channel pattern 687 may be provided to be overlapped with the second power line PL2f in the third direction D3.

Each of the first to fourth logic channel patterns 681, 684, 685, and 688 and the first to fourth filler channel patterns 682, 683, 686, and 687 may include semiconductor patterns SP, which are spaced apart from each other in the third direction D3. In some implementations, the semiconductor patterns SP may be formed of or include silicon (Si). In some implementations, the semiconductor patterns SP may be formed of or include silicon-germanium (SiGe).

The first and third logic channel patterns 681 and 685 may be the channel patterns of the first logic cell SC1f. The second and fourth logic channel patterns 684 and 688 may be the channel patterns of the second logic cell SC2f. The first to fourth filler channel patterns 682, 683, 686, and 687 may be the channel patterns of the filler cell FCf.

First source/drain patterns 671, second source/drain patterns 672, a third source/drain pattern 673, a fourth source/drain pattern 674, a fifth source/drain pattern 675, and a sixth source/drain pattern 676 may be provided.

The first source/drain patterns 671 may be the source/drain patterns of the first logic cell SC1f. The second source/drain patterns 672 may be the source/drain patterns of the second logic cell SC2f. The third to sixth source/drain patterns 673, 674, 675, and 676 may be the source/drain patterns of the filler cell FCf.

Each of the first and third logic channel patterns 681 and 685 may be interposed between the first source/drain patterns 671, which are adjacent to each other in the second direction D2. Each of the second and fourth logic channel patterns 684 and 688 may be interposed between the second source/drain patterns 672, which are adjacent to each other in the second direction D2.

The first filler channel pattern 682 may be interposed between the third and fourth source/drain patterns 673 and 674. The second filler channel pattern 683 may be interposed between the fourth source/drain pattern 674 and a second separation structure 622, which will be described below. A length of the first filler channel pattern 682 in the second direction D2 may be larger than a length of the second filler channel pattern 683 in the second direction D2.

The third filler channel pattern 686 may be interposed between a first separation structure 621, which will be described below, and the fifth source/drain pattern 675. The fourth filler channel pattern 687 may be interposed between the fifth and sixth source/drain patterns 675 and 676.

The first to sixth source/drain patterns 671, 672, 673, 674, 675, and 676 may be epitaxial patterns, which are formed by a selective epitaxial growth (SEG) process.

A first logic gate structure 651, a second logic gate structure 656, a first gate structure 652, a second gate structure 653, a third gate structure 654, and a fourth gate structure 655 may be provided.

Each of the first and second logic gate structures 651 and 656 and the first to fourth gate structures 652, 653, 654, and 655 may include a gate insulating layer GI, a gate electrode GE, a gate capping layer GP, and a gate spacer GS. The gate insulating layer GI, the gate capping layer GP, and the gate spacer GS may include an insulating material. The gate electrode GE may include a conductive material. The gate electrode GE may include portions, which are interposed between the semiconductor patterns SP. The gate electrode GE and the semiconductor pattern SP may constitute a three-dimensional field effect transistor (e.g., MBCFET or GAAFET).

A first insulating layer 612 may be provided on the first to sixth source/drain patterns 671, 672, 673, 674, 675, and 676. A second insulating layer 613 may be provided on the first insulating layer 612 and the gate capping layer GP. A third insulating layer 614 may be provided on the second insulating layer 613, and a fourth insulating layer 615 may be provided on the third insulating layer 614. The first to fourth insulating layers 612, 613, 614, and 615 may include an insulating material.

The first and second separation structures 621 and 622 may be provided. The first and second separation structures 621 and 622 may be extended in the first direction D1. In some implementations, side surfaces of the first and second separation structures 621 and 622 may be parallel to the first direction D1. The first separation structure 621 may be provided between the first logic cell SC1f and the filler cell FCf. The second separation structure 622 may be provided between the second logic cell SC2f and the filler cell FCf. The first and second separation structures 621 and 622 may include an insulating material.

The third source/drain pattern 673 may be in contact with the first separation structure 621. The fifth source/drain pattern 675 may be spaced apart from the first separation structure 621 in the second direction D2. The sixth source/drain pattern 676 may be in contact with the second separation structure 622. The fourth source/drain pattern 674 may be spaced apart from the second separation structure 622 in the second direction D2.

A distance between the gate electrode GE of the first gate structure 652 and the first separation structure 621 in the second direction D2 may be smaller than a distance between the gate electrode GE of the fourth gate structure 655 and the first separation structure 621 in the second direction D2. A distance between the gate electrode GE of the first gate structure 652 and the second separation structure 622 in the second direction D2 may be larger than a distance between the gate electrode GE of the fourth gate structure 655 and the second separation structure 622 in the second direction D2.

First active contacts AC may be provided. The first active contact AC may be provided on each of the first to sixth source/drain patterns 671, 672, 673, 674, 675, and 676. The first active contact AC may include a conductive material.

In some implementations, a metal-semiconductor compound layer may be interposed between the first active contact AC and the source/drain patterns 671, 672, 673, 674, 675, and 676. In this case, the first active contact AC may be electrically connected to the source/drain patterns 671, 672, 673, 674, 675, and 676 through the metal-semiconductor compound layer. For example, the metal-semiconductor compound layer may be formed of or include at least one of titanium silicide, tantalum silicide, tungsten silicide, nickel silicide, or cobalt silicide.

In some implementations, the first active contact AC may include a conductive pattern and a barrier pattern. The barrier pattern may cover side and bottom surfaces of the conductive pattern. For example, the conductive pattern may be formed of or include at least one of aluminum, copper, tungsten, molybdenum, or cobalt, and the barrier pattern may be formed of or include at least one of titanium, tantalum, tungsten, nickel, cobalt, titanium nitride (TiN), tantalum nitride (TaN), tungsten nitride (WN), nickel nitride (NiN), cobalt nitride (CoN), or platinum nitride (PtN).

Second active contacts 624 may be provided. The second active contact 624 may be provided on the first active contact AC. Gate contacts 625 may be provided. The gate contact 625 may be provided on the gate electrode GE.

Conductive lines 623, a first conductive structure 630, and a second conductive structure 640 may be provided in the third insulating layer 614. The conductive line 623 may be provided to electrically connect the source/drain patterns 671 and 672 of the logic cells SC1f and SC2f to the power lines PL1f and PL2f.

The first conductive structure 630 may include a first line conductive pattern 631, a second line conductive pattern 632, a third line conductive pattern 633, and a first connection conductive pattern 634. The first line conductive pattern 631 may be overlapped with the third source/drain pattern 673 and the third gate structure 654 in the third direction D3. The second line conductive pattern 632 may be overlapped with the first and fourth gate structures 652 and 655 in the third direction D3. The third line conductive pattern 633 may be overlapped with the fourth source/drain pattern 674 and the fourth gate structure 655 in the third direction D3.

The second conductive structure 640 may include a fourth line conductive pattern 641, a fifth line conductive pattern 642, a sixth line conductive pattern 643, and a second connection conductive pattern 644. The fourth line conductive pattern 641 may be overlapped with the fifth source/drain pattern 675 and the first gate structure 652 in the third direction D3. The fifth line conductive pattern 642 may be overlapped with the first and fourth gate structures 652 and 655 in the third direction D3. The sixth line conductive pattern 643 may be overlapped with the sixth source/drain pattern 676 and the second gate structure 653 in the third direction D3.

Line contacts 626 may be provided in the fourth insulating layer 615. The line contact 626 may be provided to electrically connect the power lines PL1f and PL2f to the conductive structures 630 and 640 or to electrically connect the power lines PL1f and PL2f to the conductive line 623.

In a semiconductor device according to the present disclosure, a filler cell may include line conductive patterns, and a capacitance per unit area of the filler cell may be increased.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device, comprising:
a first power line extending in a first direction;
a second power line extending in the first direction and spaced apart from the first power line in a second direction crossing the first direction;
a filler cell electrically connected to the first and second power lines; and
a first logic cell and a second logic cell spaced apart from each other in the first direction, the filler cell being interposed between the first logic cell and the second logic cell,
wherein the filler cell comprises:
a first source/drain pattern and a second source/drain pattern both electrically connected to the first power line;
a first gate electrode between the first source/drain pattern and the second source/drain pattern;
a third source/drain pattern and a fourth source/drain pattern both electrically connected to the second power line;
a second gate electrode between the third source/drain pattern and the fourth source/drain pattern;
a first line conductive pattern overlapped with the first source/drain pattern;
a second line conductive pattern overlapped with the second source/drain pattern; and
a third line conductive pattern overlapped with the third source/drain pattern and the first gate electrode,
wherein the first gate electrode, the third source/drain pattern, and the third line conductive pattern are disposed between the first line conductive pattern and the second line conductive pattern.

2. The semiconductor device of claim 1, wherein the third line conductive pattern is overlapped with the first power line.

3. The semiconductor device of claim 1, wherein the second line conductive pattern is overlapped with the second gate electrode.

4. The semiconductor device of claim 1,
wherein the filler cell further comprises a fourth line conductive pattern that is overlapped with the first gate electrode and the second gate electrode, and
wherein the third line conductive pattern is disposed between the first line conductive pattern and the fourth line conductive pattern.

5. The semiconductor device of claim 4,
wherein the filler cell further comprises a connection conductive pattern that connects the first line conductive pattern, the second line conductive pattern, and the fourth line conductive pattern to each other, and
wherein a distance between the connection conductive pattern and the second power line in the second direction is larger than a distance between the first power line and the second power line in the second direction.

6. The semiconductor device of claim 1,
wherein the filler cell further comprises a fourth line conductive pattern that is overlapped with the fourth source/drain pattern, and
wherein the second line conductive pattern, the third line conductive pattern, the second source/drain pattern, third source/drain pattern, the first gate electrode, and the second gate electrode are disposed between the first line conductive pattern and the fourth line conductive pattern.

7. The semiconductor device of claim 1,
wherein a distance between the first source/drain pattern and the first logic cell in the first direction is smaller than a distance between the third source/drain pattern and the first logic cell in the first direction, and
wherein a distance between the second source/drain pattern and the second logic cell in the first direction is larger than a distance between the fourth source/drain pattern and the second logic cell in the first direction.

8. A semiconductor device, comprising:
a first power line extending in a first direction;
a second power line extending in the first direction and spaced apart from the first power line in a second direction crossing the first direction;
a filler cell electrically connected to the first power line and the second power line; and
a first logic cell and a second logic cell spaced apart from each other in the first direction, the filler cell being interposed between the first logic cell and the second logic cell,
wherein the filler cell comprises:
a first source/drain pattern and a second source/drain pattern both electrically connected to the first power line;
a first gate electrode between the first source/drain pattern and the second source/drain pattern;
a third source/drain pattern and a fourth source/drain pattern both electrically connected to the second power line; and
a second gate electrode between the third source/drain pattern and the fourth source/drain pattern,
wherein a distance between the first source/drain pattern and the fourth source/drain pattern in the first direction is larger than a distance between the third source/drain pattern and the fourth source/drain pattern in the first direction.

9. The semiconductor device of claim 8, wherein the first gate electrode and the third source/drain pattern are overlapped with a straight line that extends in the second direction.

10. The semiconductor device of claim 8, wherein a length of the first gate electrode in the first direction is larger than a length of the second gate electrode in the first direction.

11. The semiconductor device of claim 10, wherein the filler cell further comprises:
a first line conductive pattern overlapped with the third source/drain pattern and the first gate electrode; and
a second line conductive pattern overlapped with the fourth source/drain pattern and the first gate electrode.

12. The semiconductor device of claim 8, wherein the filler cell further comprises:
a first line conductive pattern electrically connected to the first source/drain pattern;
a second line conductive pattern electrically connected to the second source/drain pattern; and
a connection conductive pattern connecting the first line conductive pattern and the second line conductive pattern to each other,
wherein the first line conductive pattern and the second line conductive pattern both extend in the second direction, and
the connection conductive pattern extends in the first direction.

13. The semiconductor device of claim 12, wherein the filler cell further comprises:
an active contact in contact with the first line conductive pattern and the first source/drain pattern; and
a line contact in contact with the first line conductive pattern and the first power line.

14. The semiconductor device of claim 13, wherein the active contact and the line contact are overlapped with each other.

15. The semiconductor device of claim 12,
wherein the second line conductive pattern is electrically connected to the second gate electrode, and
the filler cell further comprises a gate contact that is in contact with the second line conductive pattern and the second gate electrode.

16. The semiconductor device of claim 8, wherein the filler cell further comprises a plurality of line conductive patterns that are overlapped with the first gate electrode and the second gate electrode.

17. The semiconductor device of claim 8, wherein a distance between the first gate electrode and the first logic cell in the first direction is smaller than a distance between the second gate electrode and the first logic cell in the first direction.

18. A semiconductor device, comprising:
a first power line extending in a first direction;
a second power line extending in the first direction and spaced apart from the first power line in a second direction crossing the first direction;
a filler cell electrically connected to the first power line and the second power line; and
a first logic cell and a second logic cell spaced apart from each other in the first direction, the filler cell being interposed between the first logic cell and the second logic cell,
wherein the filler cell comprises:
a first source/drain pattern and a second source/drain pattern both electrically connected to the first power line;
a first gate electrode between the first source/drain pattern and the second source/drain pattern;
a third source/drain pattern and a fourth source/drain pattern electrically connected to the second power line;
a second gate electrode between the third source/drain pattern and the fourth source/drain pattern;
a first line conductive pattern overlapped with the first source/drain pattern;
a second line conductive pattern overlapped with the second source/drain pattern;
a third line conductive pattern overlapped with the third source/drain pattern and the first gate electrode;
a first active contact in contact with the first source/drain pattern and the first line conductive pattern;
a second active contact in contact with the third source/drain pattern and the third line conductive pattern;
a first line contact in contact with the first line conductive pattern and the first power line;
a second line contact in contact with the second line conductive pattern and the first power line;
a third line contact in contact with the third line conductive pattern and the second power line; and
a gate contact in contact with the first gate electrode and the third line conductive pattern,
wherein each of the first line conductive pattern, the second line conductive pattern, and the third line conductive pattern is overlapped with the first power line and the second power line.

19. The semiconductor device of claim 18, wherein the gate contact, the second active contact, and the third line contact are overlapped with a straight line that extends in the second direction.

20. The semiconductor device of claim 18, wherein the second active contact and the third line contact are overlapped with each other.
